(19) United States
(12) Patent Application Publication
(10) Pub. No.: US 2024/0292666 A1
(43) Pub. Date: Aug. 29, 2024

(54) DISPLAY DEVICE AND METHOD OF MANUFACTURING DISPLAY DEVICE

(71) Applicant: Samsung Display Co., Ltd., Yongin-si (KR)

(72) Inventors: Hyun Eok SHIN, Yongin-si (KR); Joon Yong PARK, Yongin-si (KR); Do Keun SONG, Yongin-si (KR)

(21) Appl. No.: 18/474,882

(22) Filed: Sep. 26, 2023

(30) Foreign Application Priority Data
Feb. 27, 2023 (KR) 10-2023-0026326

(51) Int. Cl. H10K 59/122; H10K 59/12

(52) U.S. Cl. CPC H10K 59/122; H10K 59/1201

(57) ABSTRACT

A display device includes a pixel circuit layer including a base layer and a pixel circuit, a first electrode on the pixel circuit layer, light emitting portions including a first light emitting portion defining first sub-pixel area and a second light emitting portion defining a second sub-pixel area, and a partition wall between the first and second light emitting portions, wherein the partition wall includes a first layer, a second layer on the first layer, and a third layer on the second layer, wherein the first layer has a first thickness, the second layer has a second thickness, the third layer has a third thickness, and the partition wall has a fourth thickness that is a sum of the first thickness to the third thickness, and wherein the first thickness and a thickness of the light emitting portion correspond to each other.

### CROSS-REFERENCE TO RELATED APPLICATION

The present application claims priority to and the benefit of Korean Patent Application No. 10-2023-0026326 filed in the Korean Intellectual Property Office on Feb. 27, 2023, the entire content of which is incorporated herein by reference.

### BACKGROUND

### 1. Field

Aspects of some embodiments of the present disclosure relate to a display device and a manufacturing method thereof.

### 2. Description of the Related Art

As information technology develops, the use of a display device, which is a connection medium between a user and information, is increasing. Accordingly, the use of display devices such as organic light emitting diode (OLED) display devices, liquid crystal display devices (LCDs), electrophoretic display devices, and quantum dot display devices is increasing.

The organic light emitting diode (OLED) display device is a self-light emitting display device, and has excellent response speed, viewing angle, and contrast ratio, and is being studied as a next-generation display.

Meanwhile, research continues to increase resolution of the organic light emitting diode display device, and in order to increase the resolution of the display device, it is desirable to reduce a width of a partition wall between pixels.

The above information disclosed in this Background section is only for enhancement of understanding of the background and therefore the information discussed in this Background section does not necessarily constitute prior art.

### SUMMARY

Aspects of embodiments of the present disclosure are directed to a display device and a manufacturing method thereof that may reduce a width of a partition wall between pixels.

According to some embodiments of the present disclosure, there is provided a display device including: a pixel circuit layer including a base layer and a pixel circuit; a first electrode on the pixel circuit layer; light emitting portions on the first electrode and including a first light emitting portion defining a first sub-pixel area and a second light emitting portion defining a second sub-pixel area; and a partition wall between the first light emitting portion and the second light emitting portion, wherein the partition wall includes a first layer, a second layer on the first layer, and a third layer on the second layer, wherein the first layer has a first thickness, the second layer has a second thickness, the third layer has a third thickness, and the partition wall has a fourth thickness that is a sum of the first thickness to the third thickness, wherein the light emitting portions have a thickness of a light emitting portion, and wherein the first thickness and the thickness of the light emitting portion correspond to each other.

In some embodiments, a difference between the first thickness and the thickness of the light emitting portion is 0.1 μm or less.

In some embodiments, the first thickness is more than half of the fourth thickness.

In some embodiments, the first thickness is 0.2 μm to 0.3 μm.

In some embodiments, the first layer has a first width, the second layer has a second width, and the third layer has a third width, and the first width is greater than the second width.

In some embodiments, at least a portion of the first layer does not overlap the second layer in a plan view.

In some embodiments, the third width corresponds to the first width.

In some embodiments, the second width is 0.15 μm to 0.25 μm.

In some embodiments, a difference between the third width and the first width is 0.05 μm or less.

In some embodiments, the first layer and the third layer include a same metal, and the second layer includes a different metal than the first layer and the third layer.

In some embodiments, the first layer and the third layer include titanium (Ti), and the second layer includes molybdenum (Mo).

In some embodiments, the display device further includes: a second electrode on the light emitting portions, wherein the first electrode is an anode electrode, wherein the second electrode is a cathode electrode, and wherein the second electrode is in contact with at least a portion of the second layer.

According to some embodiments of the present disclosure, there is provided a manufacturing method of a display device, the method including: forming a pixel circuit layer including a pixel circuit on a base layer; patterning a first electrode on the pixel circuit layer; patterning a partition wall on the pixel circuit layer; patterning a light emitting portion; and patterning a second electrode electrically connected to the light emitting portion, wherein the patterning of the light emitting portion includes patterning a first light emitting portion defining a first sub-pixel area and a second light emitting portion defining a second sub-pixel area, wherein the patterning of the partition wall includes depositing a first layer, a second layer on the first layer, and a third layer on the second layer, wherein the first layer has a first thickness, the second layer has a second thickness, and the third layer has a third thickness, wherein the partition wall has a fourth thickness that is a sum of the first thickness to the third thickness, and wherein the first thickness and the a thickness of the light emitting portion correspond to each other.

In some embodiments, a difference between the first thickness and the thickness of the light emitting portion is 0.05 μm or less.

In some embodiments, the first thickness is greater than the second thickness and the third thickness.

In some embodiments, the thickness of the light emitting portion is 0.2 μm to 0.3 μm.

In some embodiments, the patterning of the partition wall includes etching the second layer deeper than the first layer and the third layer.

In some embodiments, the third layer forms a protrusion having a protruding length.

In some embodiments, the protruding length is 0.1 μm to 0.2 μm.

In some embodiments, the manufacturing method of the display device further includes: patterning the second electrode on the light emitting portion, wherein the patterning of the light emitting portion includes depositing the light emitting portion by using an evaporator, and wherein the patterning of the second electrode includes depositing the second electrode by using a rotary sputter.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates a schematic top plan view of a display device according to some embodiments of the present disclosure;

FIG. 2 illustrates a schematic cross-sectional view of a display device according to some embodiments of the present disclosure;

FIG. 3 illustrates a schematic cross-sectional view of a light emitting element according to some embodiments of the present disclosure;

FIG. 4 illustrates a schematic block diagram of an electrical connection structure for a light emitting element according to some embodiments of the present disclosure;

FIG. 5 illustrates a schematic top plan view of a display device according to some embodiments of the present disclosure;

FIG. 6 illustrates a schematic cross-sectional view taken along the line A-A′ of FIG. 5, according to some embodiments of the present disclosure;

FIG. 7 illustrates a schematic enlarged view of the area S1 of FIG. 6, according to some embodiments of the present disclosure;

FIG. 8 illustrates a flowchart of a manufacturing method of a display device according to some embodiments of the present disclosure; and

FIGS. 9 to 17 illustrate cross-sectional views of process steps of a manufacturing method of a display device according to some embodiments of the present disclosure.

### DETAILED DESCRIPTION

Since the disclosure may be variously modified and have various forms, embodiments will be illustrated and described in detail in the following. This, however, by no means restricts the disclosure to the specific embodiments, and it is to be understood as embracing all included in the spirit and scope of the disclosure changes, equivalents, and substitutes.

Terms such as first, second, and the like will be used only to describe various constituent elements, and are not to be interpreted as limiting these constituent elements. The terms are only used to differentiate one constituent element from other constituent elements. For example, a first constituent element could be termed a second constituent element, and similarly, a second constituent element could be termed as a first constituent element, without departing from the scope of the disclosure. Singular forms are intended to include plural forms unless the context clearly indicates otherwise.

The disclosure relates to a display device and a manufacturing method thereof. Hereinafter, a display device and a manufacturing method thereof according to some embodiments will be described with reference to the accompanying drawings.

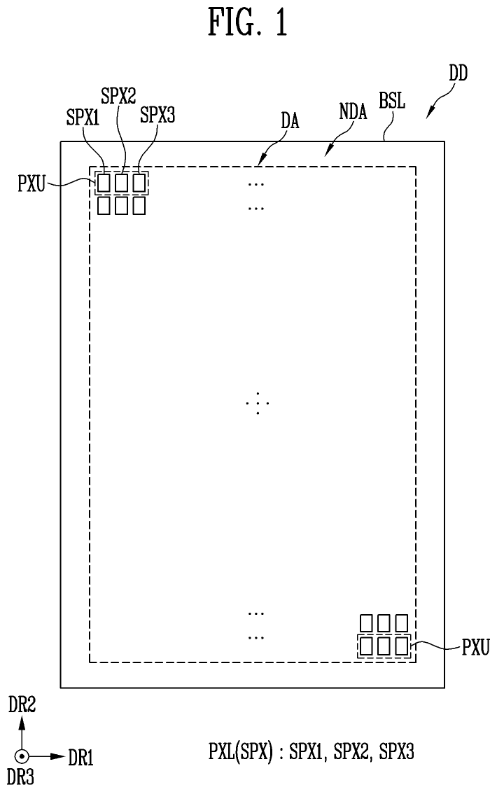

FIG. 1 illustrates a schematic top plan view of a display device according to some embodiments of the present disclosure.

A display device DD is configured to emit light. The display device DD includes a light emitting element LD. According to some embodiments, the display device DD is a device displaying a moving image or a still image. The display device DD may be utilized as a display screen of a portable electronic device such as a mobile phone, a smart phone, a tablet personal computer (PC), a smart watch, a watch phone, a mobile communication terminal, an electronic note, an electronic book, a portable multimedia players (PMP), a navigation device, and an ultra mobile PC (UMPC), and may be utilized as display screens of various products such as a television set, a laptop computer, a monitor, a billboard, an Internet of things (IOT). However, the applications of the display device DD are not limited to the specific examples above.

The display device DD may be formed as a flat surface having a rectangular shape having a short side extending along a first direction DR1 and a long side extending along a second direction DR2 crossing the first direction DR1. A corner at which the short side of the first direction DR1 and the long side of the second direction DR2 meet may be rounded to have a set or predetermined curvature or may be formed to have a right angle. The flat shape of the display device DD is not limited to a quadrangular shape, and may be formed in a round shape such as another polygonal, circular, or elliptical shape. The display device DD may be formed to be flat, but is not limited thereto. For example, the display device DD may include curved portions that are formed at left and right ends and have a constant curvature or a variable curvature. In addition, the display device DD may be flexibly formed to be bent, curved, folded, or rolled.

The display device DD may include a display area DA and a non-display area NDA. The non-display area NDA may refer to an area other than the display area DA. The non-display area NDA may surround at least a portion of the display area DA.

A base layer BSL may form a base member of the display device DD. The base layer BSL may be a rigid or flexible substrate or film. For example, the base layer BSL may be a hard substrate made of glass or tempered glass, a flexible substrate (or a thin film) made of a plastic or metallic material, or at least one layered insulating layer. According to some embodiments, the base layer BSL includes silicon (Si). The material and/or physical properties of the base layer BSL are not particularly limited. According to some embodiments, the base layer BSL is substantially transparent. As used herein, the term “substantially transparent” may mean that most of the incoming light passes through without being absorbed or reflected In other embodiments, the base layer BSL is translucent or opaque. In addition, the base layer BSL may include a reflective material according to some examples.

The display area DA may refer to an area in which a pixel PXL is disposed. The non-display area NDA may refer to an area in which a pixel PXL is not disposed (e.g., an area in which no pixels PXL exist). In the non-display area NDA, the driving circuit part, wires, and pads connected to the pixel PXL of the display area DA may be disposed.

According to some examples, the pixels PXL (or sub-pixels SPX) may be arranged according to a stripe or PENTILE™ arrangement structure. However, embodiments of the present disclosure are not limited thereto.

According to some embodiments, the pixel PXL includes the light emitting element LD. The pixel PXL (or sub-pixels SPX) may include a first sub-pixel SPX1, a second sub-pixel SPX2, and a third sub-pixel SPX3. At least one of the first sub-pixel SPX1, the second sub-pixel SPX2, and the third sub-pixel SPX3 may form one pixel unit PXU capable of emitting light of various suitable colors.

For example, each of the first sub-pixel SPX1, the second sub-pixel SPX2, and the third sub-pixel SPX3 may emit light of single color. In some examples, the first sub-pixel SPX1 may be a red pixel emitting red (e.g., first color) light, and the second sub-pixel SPX2 may be a green pixel emitting green (e.g., second color) light, and the third sub-pixel SPX3 may be a blue pixel emitting blue (e.g., third color) light. The color, type, and/or number of the first sub-pixel SPX1, the second sub-pixel SPX2, and the third sub-pixel SPX3 configuring each pixel unit PXU are not limited to a specific example.

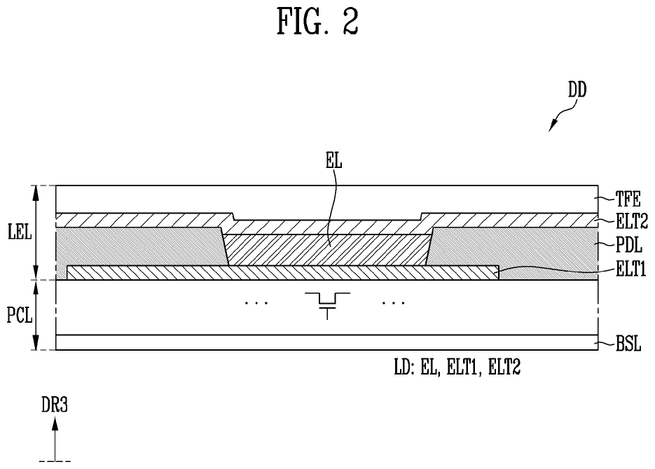

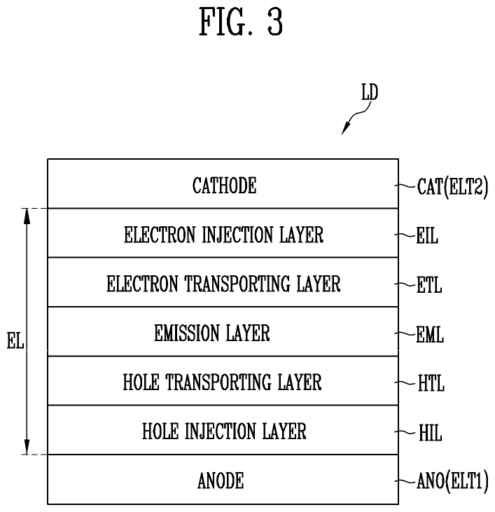

FIG. 2 illustrates a schematic cross-sectional view of a display device according to some embodiments of the present disclosure. FIG. 3 illustrates a schematic cross-sectional view of a light emitting element according to some embodiments of the present disclosure.

Referring to FIG. 2 and FIG. 3, the display device DD may include a pixel circuit layer PCL and a light-emitting-element layer LEL.

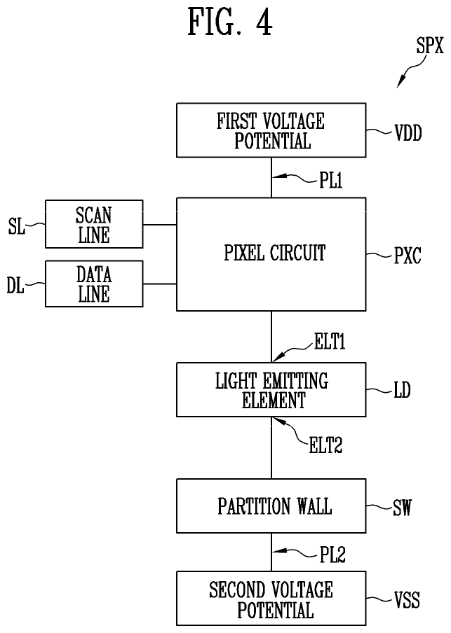

The pixel circuit layer PCL may be a layer including a pixel circuit PXC (see, e.g., FIG. 4) for driving the light emitting elements LD. The pixel circuit layer PCL may include the base layer BSL, conductive layers for forming pixel circuits, and insulating layers disposed between the conductive layers.

According to some embodiments, the pixel circuit PXC includes a thin film transistor, and is electrically connected to a light emitting element LD to provide an electrical signal for the light emitting element LD to emit light.

The light-emitting-element layer LEL may be disposed on the pixel circuit layer PCL. According to some embodiments, the light-emitting-element layer LEL includes the light emitting element LD, a pixel defining film PDL, and an encapsulation film TFE.

The light emitting element LD may be disposed on the pixel circuit layer PCL. According to some embodiments, the light emitting element LD includes a first electrode ELT1, a light emitting portion EL, and a second electrode ELT2.

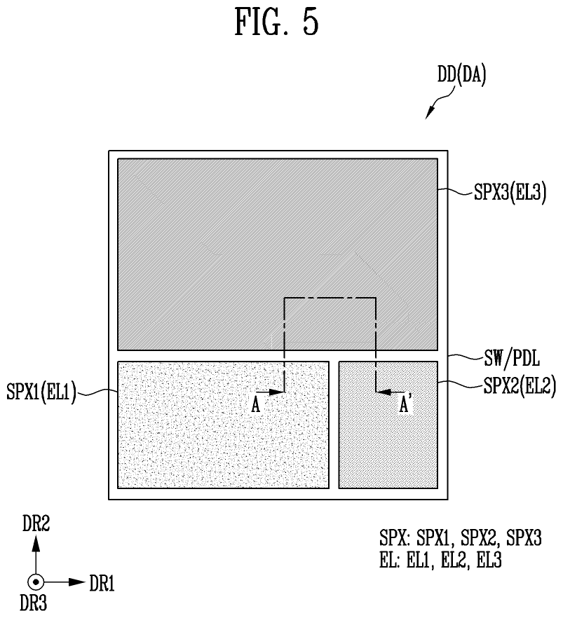

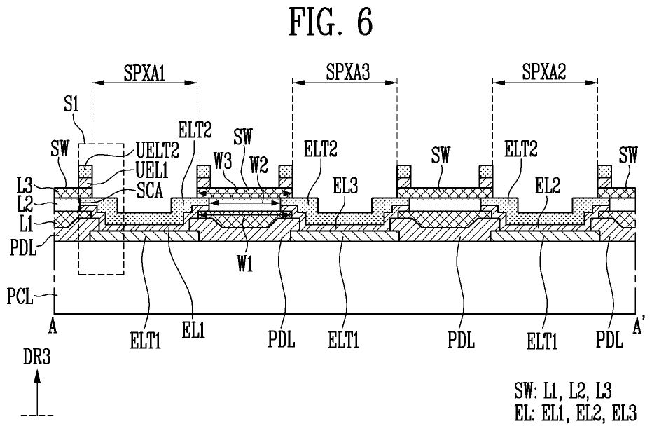

According to some embodiments, the light emitting portion EL is disposed in an area (e.g., a first sub-pixel area SPXA1, a second sub-pixel area SPXA2, or a third sub-pixel area SPXA3 of FIG. 6) defined by the pixel defining film PDL and a partition wall SW (see, e.g., FIG. 5). One surface of the light emitting portion EL may be electrically connected to the first electrode ELT1, and the other surface of the light emitting portion EL may be electrically connected to the second electrode ELT2.

The first electrode ELT1 may be an anode electrode ANO for the light emitting portion EL, and the second electrode ELT2 may be a cathode electrode CAT for the light emitting portion EL. According to some embodiments, the first electrode ELT1 and the second electrode ELT2 includes a conductive material. For example, the first electrode ELT1 may include a conductive material including a reflective property, and the second electrode ELT2 may include a transparent conductive material; however, embodiments of the present disclosure are not limited thereto. The first electrode ELT1 may be the cathode electrode CAT for the light emitting portion EL, and the second electrode ELT2 may be the anode electrode ANO for the light emitting portion EL.

The light emitting portion EL may have a multi-layered thin film structure including a light generation layer (e.g., an emission layer EML). The light emitting portion EL may include a hole injection layer HIL for injecting holes, a hole transport layer HTL having high (e.g., excellent) hole transportability and suppressing the movement of electrons that are not combined in an emission layer EML to increase the chance of recombination of holes and electrons, an emission layer EML emitting light by recombination of injected electrons and holes, an electron transport layer ETL for smoothly transporting electrons to the emission layer, and an electron injection layer EIL for injecting electrons. The light emitting portion EL may emit light based on an electrical signal provided from the anode electrode ANO (e.g., the first electrode ELT1) and the cathode electrode CAT (e.g., the second electrode ELT2).

The pixel defining film PDL may be disposed on the pixel circuit layer PCL to define a position at which the light emitting portion EL is disposed. At least a portion of the pixel defining film PDL may be disposed on the first electrode ELT1. The pixel defining film PDL may be disposed on the pixel circuit layer PCL to expose at least a portion of the first electrode ELT1. The pixel defining film PDL may include an organic material. According to some embodiments, the pixel defining film PDL includes one or more of an acrylic resin, an epoxy resin, a phenol resin, a polyamide resin, and a polyimide resin. However, embodiments of the present disclosure are not limited thereto.

The encapsulation film TFE may be disposed on the light emitting element LD (e.g., the second electrode ELT2). The encapsulation film TFE may offset a level difference generated by the light emitting element LD and the pixel defining film PDL. The encapsulation film TFE may include a plurality of insulating films covering the light emitting element LD. According to some embodiments, the encapsulation film TFE has a structure in which an inorganic film and an organic film are alternately stacked. According to some embodiments, the encapsulation film TFE is a thin film encapsulation film.

FIG. 4 illustrates a schematic block diagram of an electrical connection structure for a light emitting element according to some embodiments of the present disclosure. For example, FIG. 4 may illustrate an electrical connection structure including a pixel circuit PXC corresponding to each sub-pixel SPX.

Referring to FIG. 4, the sub-pixel SPX may include the pixel circuit PXC configured to drive the light emitting element LD.

The pixel circuit PXC may include one or more circuit elements. For example, the pixel circuit PXC may include three transistors and a storage capacitor. For example, the pixel circuit PXC may include a driving transistor, a switching transistor, and a storage capacitor. However, embodiments of the present disclosure are not limited thereto.

The pixel circuit PXC may be electrically connected to a scan line SL and a data line DL. The scan line SL may supply a scan signal to the pixel circuit PXC, and may be electrically connected to a gate electrode of the switching transistor of the pixel circuit PXC according to some embodiments. The light emitting element LD may be configured to emit light corresponding to a data signal provided from the data line DL.

The pixel circuit PXC may be electrically connected to a first power line PL1 and a second power line PL2. For example, the first electrode ELT1 of the light emitting element LD may be electrically connected to the pixel circuit PXC and the first power line PL1, and the second electrode ELT2 of the light emitting element LD may be electrically connected to the second power line PL2. According to some embodiments, the second power line PL2 is formed on the pixel circuit layer PCL in the display area DA. Alternatively, in other embodiments, the second power line PL2 is disposed in the non-display area NDA. Accordingly, the second power line PL2 may be configured to supply second power to the light emitting element LD.

The power of the first power line PL1 and the power of the second power line PL2 may have different potentials. For example, the power of the first power line PL1 may be a high-potential pixel power supplied from a first voltage potential VDD, and the power of the second power line PL2 may be a low-potential pixel power supplied from a second voltage potential VSS. A potential difference between the power of the first power line PL1 and the power of the second power line PL2 may be set to a threshold voltage or higher of the light emitting elements LD.

The first power line PL1 may be electrically connected to the pixel circuit PXC (e.g., a driving transistor). The second power line PL2 may be electrically connected to the cathode electrode (e.g., the second electrode ELT2) of the light emitting element LD.

According to some embodiments, the second power line PL2 is electrically connected to the second electrode ELT2 through a partition wall SW. For example, the partition wall SW may electrically connect the second electrode ELT2 and the second power line PL2. Further details of the partition wall SW will be described later with reference to the drawings after FIG. 5.

Each light emitting element LD may be connected in a forward direction (e.g., be electrically forward biased) between the first power line PL1 and the second power line PL2 to effectively form a light source. These effective light sources may be collected or grouped together to form the light emitting elements LD of the sub-pixel SPX.

The light emitting elements LD may emit light with luminance corresponding to a driving current supplied through the pixel circuit PXC. During each frame period, the pixel circuit PXC may supply a driving current corresponding to the data signal to the light emitting element LD. The light emitting element LD may emit light with a luminance corresponding to a current flowing therethrough.

FIG. 5 illustrates a schematic top plan view of a display device according to some embodiments of the present disclosure. FIG. 5 illustrates a portion of the display area DA. FIG. 5 illustrates a planar positional relationship between the light emitting portions EL, the pixel defining film PDL, and the partition wall SW separated from each other to form the sub-pixels SPX.

Referring to FIG. 5, the light emitting portion EL, the pixel defining film PDL, and the partition wall SW may be disposed in the display area DA.

The light emitting portion EL may include a first light emitting portion EL1 for forming a first sub-pixel SPX1 that emits light of a first color, a second light emitting portion EL2 for forming a second sub-pixel SPX2 that emits light of a second color, and a third light emitting portion EL3 for forming a third sub-pixel SPX3 that emits light of a third color.

For example, the light emitting portion EL may be selectively disposed in a partial area of the display area DA to define areas in which lights of different colors are emitted. According to some embodiments, the first light emitting portion EL1 forms a first light emitting element emitting light of a first color, the second light emitting portion EL2 may form a second light emitting element emitting light of a second color, and the third light emitting portion EL3 may form a third light emitting element emitting light of a third color.

Each of the light emitting portions EL may be disposed within an area surrounded by the partition wall SW. For example, the partition wall SW may be patterned to surround at least a partial area of the display area DA.

The partition wall SW may be a connection member capable of providing an electrical signal to the light emitting element LD. The partition wall SW may be configured to supply a cathode signal to the light emitting element LD. For example, the partition wall SW may be electrically connected to the second electrode ELT2.

The partition wall SW may be disposed at a peripheral portion of each of the light emitting portions EL. The partition wall SW may surround at least a portion of each of the light emitting portions EL in a plan view. The partition wall SW may be disposed in a boundary area between adjacent light emitting portions EL (or adjacent sub-pixels SPX).

The partition wall SW may also be referred to as a side wall.

The pixel defining film PDL may be disposed at a peripheral portion of the light emitting portions EL. The pixel defining film PDL may surround at least a portion of each of the light emitting portions EL. According to some embodiments, the pixel defining film PDL overlaps the light emitting portions EL in a plan view. The pixel defining film PDL may overlap the partition wall SW in a plan view.

FIG. 6 illustrates a schematic cross-sectional view taken along line A-A′ of FIG. 5. FIG. 6 may be a schematic cross-sectional view of the display device DD according to some embodiments of the present disclosure. FIG. 6 illustrates the first light emitting portion EL1, the second light emitting portion EL2, and the third light emitting portion EL3 among the light emitting portions EL, but for better understanding and ease of description, they are referred to as the light emitting portions EL, and the technical characteristics thereof are described below.

Referring to FIG. 6, the first electrode ELT1 may be disposed on the pixel circuit layer PCL. The first electrodes ELT1 may be disposed to be spaced apart from each other. The first electrode ELT1 may define an area in which the pixel defining film PDL and the partition wall SW are disposed.

The pixel defining film PDL may be disposed on the pixel circuit layer PCL. At least some portions of the pixel defining film PDL may be spaced apart from each other with the light emitting portion EL interposed therebetween. The pixel defining film PDL may define a position in which the light emitting portion EL is disposed. At least a portion of the pixel defining film PDL may be disposed on the first electrode ELT1. The pixel defining film PDL may be disposed adjacent to the first electrode ELT1. The pixel defining film PDL may expose at least a portion of the first electrode ELT1. At least a portion of the pixel defining film PDL may overlap the first electrode ELT1 in a plan view. The pixel defining film PDL may cover one end portion of the first electrode ELT1.

The partition wall SW may be disposed on the pixel defining film PDL. At least a portion of the partition wall SW may overlap at least a portion of the first electrode ELT1 in a plan view. At least a portion of the partition wall SW may not overlap at least a portion of the pixel defining film PDL in a plan view. The partition wall SW may be disposed between the light emitting portions EL.

The partition wall SW may include a multi-layered structure of three or more layers. For example, the partition wall SW may include a first layer L1, a second layer L2, and a third layer L3. According to some embodiments, the partition wall SW includes a triple-layered structure. However, embodiments of the present disclosure are not limited thereto. Hereinafter, the partition wall SW will be described based on a triple-layered structure including the first layer L1, the second layer L2, and the third layer L3.

The first layer L1, the second layer L2, and the third layer L3 may be sequentially stacked in a thickness direction (e.g., a third direction DR3) of the base layer BSL. For example, the first layer L1 may be disposed on the pixel defining film PDL. The second layer L2 may be disposed on the first layer L1. The third layer L3 may be disposed on the second layer L2.

The first layer L1 may have a first width W1. The second layer L2 may have a second width W2. The third layer L3 may have a third width W3. The first to third widths W1 to W3 may be thicknesses in a direction perpendicular to the third direction DR3 (e.g., a length direction of the pixel circuit layer PCL).

According to some embodiments, the width of each of the first layer L1, the second layer L2, and the third layer L3 are defined based on a direction in which the light emitting portions EL are spaced apart from each other. According to some embodiments, the width of each of the first layer L1, the second layer L2, and the third layer L3 are defined based on a direction in which adjacent sub-pixels SPX are spaced apart from each other.

According to some embodiments, the second width W2 is less than the first width W1 and the third width W3. Accordingly, the second layer L2 may have a structure that is further inward (i.e., away from the center of the corresponding sub-pixel area SPXA1/2/3) than the first layer L1 and the third layer L3. The partition wall SW may have an under-cut structure in which the first layer L1 and the third layer L3 protrude outward (i.e., toward the center of the corresponding sub-pixel area SPXA1/2/3) more than the second layer L2.

For example, the first layer L1 and the third layer L3 may protrude outward more than the second layer L2 on both sides, and accordingly, the partition wall SW may have an ‘I’-shaped structure.

When the first layer L1 does not protrude outward more than the second layer L2 as a result of the first width W1 and the second width W2 being same, only the third layer L3 of the partition wall SW may have a ‘T’-shaped structure protruding outward in the width direction of the partition wall SW. The ‘I’-shaped structure may provide a relatively more stable structure than the ‘T’-shaped structure because the lower disposed layer may stably support the upper disposed layer. That is, the structure of the partition wall SW according to some embodiments provides structural stability.

In addition, as the first layer L1 protrudes outward more than the second layer L2, at least a portion of the first layer L1 may not overlap the second layer L2 in a plan view. In this case, the deposition accuracy of the light emitting portion EL may be improved (e.g., increased), and the need for excessively extending the width of the partition wall SW may be reduced or substantially reduced. That is, according to the structure of some embodiments, even if the width of the partition wall SW is appropriately reduced, the deposition process is appropriately performed, so that a side contact area SCA may be substantially secured (e.g., is reliably produced). As a result, a structure in which the width of the partition wall SW is reduced may be manufactured without generating substantial process noise, and the display device DD with high resolution may be provided. Process characteristics for this will be described later in more detail with reference to FIG. 16.

According to some examples, the first width W1 and the third width W3 may correspond to each other. The first width W1 and the third width W3 may be substantially the same. As used herein, “the widths are substantially the same” may mean “a difference in width is 0.05 μm or less”. In some examples, the first width W1 and the third width W3 may be 0.4 μm or more and 0.6 μm or less. The first width W1 and the third width W3 may be 0.45 μm or more and 0.55 μm or less. The second width W2 may be 0.15 μm or more and 0.25 μm or less. However, embodiments of the present disclosure are not limited thereto.

According to some embodiments, the first layer L1 and the third layer L3 includes the same or substantially the same material and be etched and manufactured in the same process. For example, the first layer L1 and the third layer L3 may include (e.g., include equal amounts of) one or more of transition metal materials such as titanium (Ti), niobium (Nb), tantalum (Ta), and the like. The first layer L1 and the third layer L3 may include a transition metal material to have high (e.g., excellent) chemical resistance.

However, embodiments of the present disclosure are not limited to the example described above. The first layer L1 and the third layer L3 may include different transition metals, and may include a conductive material other than a transition metal.

The second layer L2 may include a metal having low contact resistance. For example, the second layer L2 may include molybdenum (Mo). In some examples, the second layer L2 may include one or more of molybdenum alloys such as MoNiTi, MoAlTi, MoAl, MoW, MoAlTa Mo—Ti, MoTa, and MoNb.

Molybdenum (Mo) may have high (e.g., excellent) oxidation resistance. In addition, molybdenum (Mo) may have a smaller contact resistance than that of aluminum (Al) that may be utilized as a general wire material. For example, the contact resistance of molybdenum (Mo) may be about 1/10 of that of aluminum (Al). Molybdenum (Mo) has low contact resistance, so that it may easily make electrical contact with other materials. Accordingly, the second layer L2 may include molybdenum (Mo), and thus, the second electrode ELT2 and the second layer L2 may be in stable contact with each other. According to some embodiments, because the second electrode ELT2 is electrically connected to the second layer L2 having generally low contact resistance, reliability of the electrical signal may be b (e.g., be increased).

As a result, even when the second width W2 is reduced, the second electrode ELT2 and the second layer L2 may stably electrically contact each other, so that the width of the partition wall SW between the sub-pixels SPX may be reduced, thus enabling a high-resolution display device.

The light emitting portion EL may be disposed on the first electrode ELT1. The light emitting portion EL may overlap at least a portion of the first electrode ELT1 in a plan view. At least a portion of the light emitting portion EL may be disposed on at least a portion of the pixel defining film PDL. At least a portion of the light emitting portion EL may contact at least a portion of the pixel defining film PDL.

At least a portion of the light emitting portion EL may contact at least a portion of the side surface of the second layer L2. The light emitting portion EL may expose the remaining portion of the side surface of the second layer L2. As the light emitting portion EL does not cover the remaining portion of the side surface of the second layer L2, at least a portion of the second layer L2 is exposed, so that the side contact area SCA in which the second electrode ELT2 and the second layer L2 may electrically contact each other may be provided. As the side contact area SCA of the partition wall SW is provided, the second electrode ELT2 may then be deposited to be electrically connected to the second layer L2 in the side contact area SCA.

The second electrode ELT2 may be disposed on the light emitting portion EL. At least a portion of the second electrode ELT2 may electrically contact the second layer L2 in the side contact area SCA of the partition wall SW. The second electrode ELT2 may electrically contact one surface of the light emitting portion EL.

According to some embodiments, the display device DD further includes an upper light emitting portion UEL1 and an upper second electrode UELT2.

The upper light emitting portion UEL1 may be disposed on at least a portion of the third layer L3. The upper light emitting portion UEL1 may contact at least a portion of the third layer L3. The upper light emitting portion UEL1 may be formed in the same deposition process as the light emitting portion EL.

The upper second electrode UELT2 may be disposed on the upper light emitting portion UEL1. The upper second electrode UELT2 may be formed in the same deposition process and may include the same or substantially the same material, as the second electrode ELT2.

Among the areas in which the light emitting portion EL is disposed, in a plan view, areas that do not overlap the partition wall SW include the first sub-pixel area SPXA1, the second sub-pixel area SPXA2, and the third sub-pixel area SPXA3. The first sub-pixel area SPXA1, the second sub-pixel area SPXA2, and the third sub-pixel area SPXA3 may be areas in which the first sub-pixel SPX1, the second sub-pixel SPX2, and the third sub-pixel SPX3 are defined, respectively.

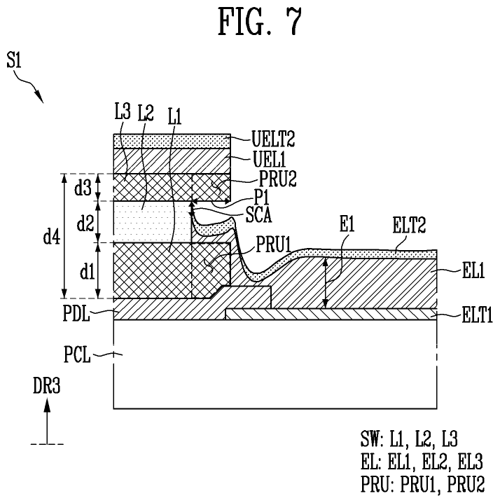

FIG. 7 illustrates a schematic enlarged view of an area S1 of FIG. 6. FIG. 7 may be a cross-sectional view of the display device DD in which the structure of the partition wall SW of FIG. 6 is enlarged. Hereinafter, the structure of the partition wall SW according to the disclosure will be described in more detail with reference to FIG. 7. Descriptions that may be redundant to those described above are simplified or are not repeated.

The second layer L2 may be etched relatively deeper in a lateral direction (e.g., a length direction of the base layer BSL) than the first layer L1 and the third layer L3. As the second layer L2 is etched more than the first layer L1, the first layer L1 may form a first protrusion PRU1. As the second layer L2 is etched more than the third layer L3, the third layer L3 may form a second protrusion PRU2. A protrusion PRU may include the first protrusion PRU1 and the second protrusion PRU2. The protrusion PRU may form a tip. The protrusion PRU may refer to a portion that protrudes further outward from edge of the first layer L1 and the third layer L3 compared with the second layer L2. The protrusion PRU may have a protruding length P1 protruding from an end portion of the second layer L2.

In a plan view, the light emitting portion EL may have a substantially uniform thickness E1 in at least a portion of an area overlapping the first electrode ELT1. The thickness E1 of the light emitting portion may refer to the largest thickness among the thickness ranges of the light emitting portion EL.

The first layer L1 may have a first thickness d1. The second layer L2 may have a second thickness d2. The third layer L3 may have a third thickness d3. Accordingly, the partition wall SW may have a fourth thickness d4 that is a sum of the first thickness d1 to the third thickness d3.

The first thickness d1 may be about 0.2 μm to about 0.3 μm. The first thickness d1 may be ½ or more of the fourth thickness d4. The first layer L1 may have the thickest first thickness d1 in the multi-layered structure of the partition wall SW. The first thickness d1 may be greater than the second thickness d2 and the third thickness d3.

The first thickness d1 may correspond to the thickness E1 of the light emitting portion. Here, the meaning of “corresponding to the thickness” may mean “the difference in thickness is 0.1 μm or less”. As the first thickness d1 corresponds to the thickness E1 of the light emitting portion, the first thickness d1 and the thickness E1 of the light emitting portion may have similar thickness ranges.

As the first thickness d1 is similar to the thickness E1 of the light emitting portion and the first layer L1 protrudes more than the second layer L2, the light emitting portion EL may not entirely cover the side surface of at least the second layer L2 during deposition. In this case, the side contact area SCA may be carefully secured (e.g., reliably produced). This will be described in more detail with reference to FIG. 16.

The light emitting portion EL may not contact at least a portion of the second layer L2 in the side contact area SCA. Accordingly, a portion of the second layer L2 that does not contact the light emitting portion EL may be exposed and the side contact area SCA may be provided. As the side contact area SCA is provided, an electrical connection structure may be formed between the partition wall SW and the second electrode ELT2 in the display device DD.

The second thickness d2 may be about 0.1 μm to about 0.2 μm.

The third thickness d3 may be about 0.05 μm to about 0.1 μm.

The fourth thickness d4 may be about 0.35 μm to about 0.6 μm. However, embodiments of the present disclosure are not limited thereto.

The protruding length P1 may be about 0.1 μm to about 0.2 μm. In the display device DD according to the disclosure, the second layer L2 may be etched with a minimum depth, and thus the protruding length P1 may be reduced. This will be described later with reference to FIG. 16.

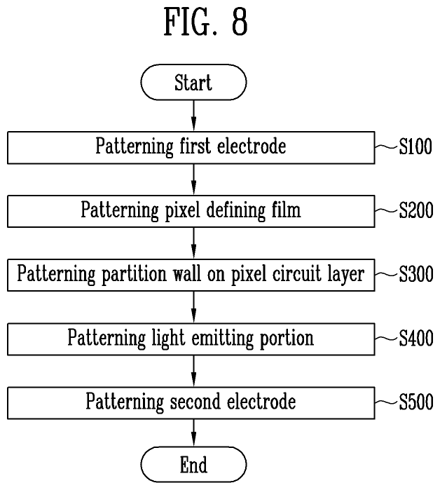

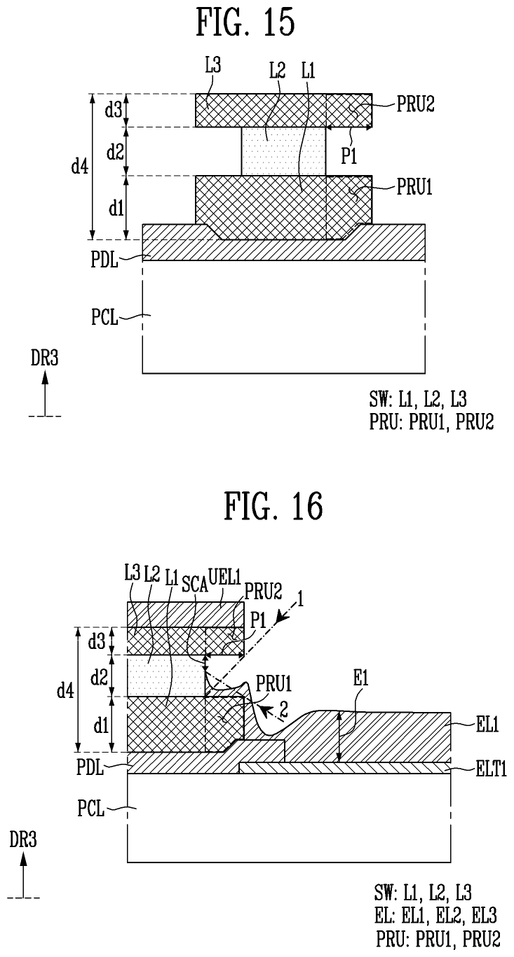

Hereinafter, a manufacturing method of the display device DD according to some embodiments will be described with reference to FIG. 8 to FIG. 17. Descriptions that may be redundant to those described above are simplified or are not repeated.

FIG. 8 illustrates a flowchart of a manufacturing method of a display device according to some embodiments of the present disclosure.

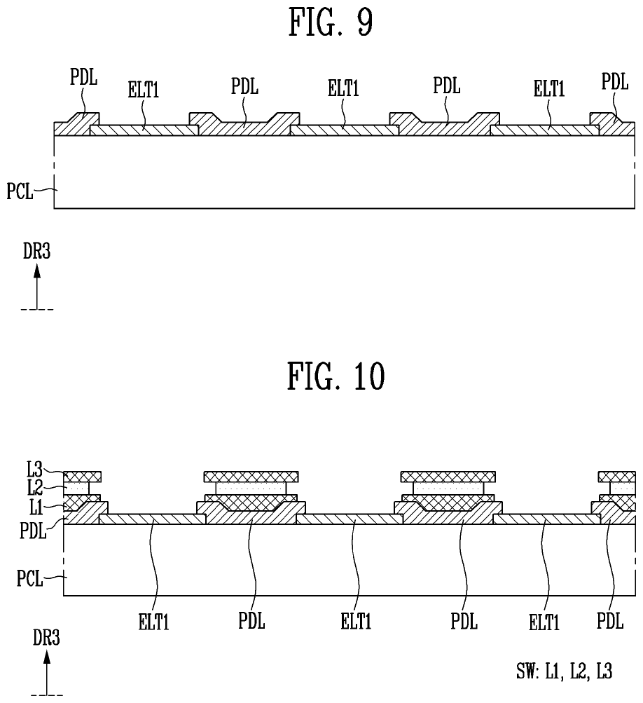

FIGS. 9 to 17 illustrate cross-sectional views of process steps of a manufacturing method of a display device according to some embodiments of the present disclosure.

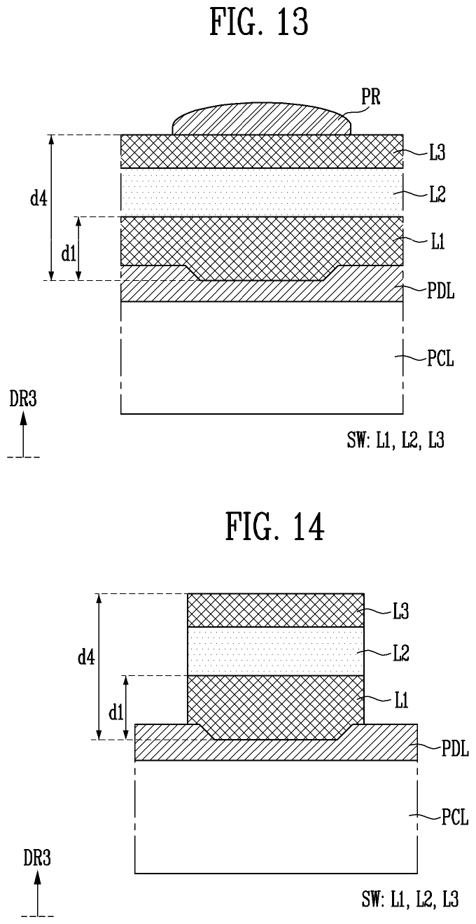

Particularly, FIG. 13 to FIG. 17 are drawings showing some steps of a manufacturing method of the display device DD according to some embodiments, and are cross-sectional views showing a manufacturing method of the partition wall SW. FIG. 13 to FIG. 17 may be cross-sectional views showing in more detail a method for manufacturing the partition wall SW structure of FIG. 10.

Referring to FIG. 8, the manufacturing method of the display device DD according to some embodiments includes patterning a first electrode (S100), patterning a pixel defining film (S200), patterning a partition wall on a pixel circuit layer (S300), patterning a light emitting portion (S400), and patterning a second electrode (S500).

The patterning of a first electrode ELT1 (S100) and the patterning of a pixel defining film PDL (S200) will be described with reference to FIG. 8 and FIG. 9.

Before patterning the first electrode ELT1, the pixel circuit layer PCL including the pixel circuit PXC for driving the light emitting elements LD may be formed on the base layer BSL. The pixel circuit layer PCL may be formed to include conductive layers and insulating layers disposed between the conductive layers.

According to some embodiments, components disposed on the base layer BSL may be formed through a typical patterning process (e.g., a photolithography process) using a mask.

The patterning of a first electrode (S100) includes depositing the first electrode ELT1 on the pixel circuit layer PCL. According to some examples, when the first electrode ELT1 is deposited, it may be electrically connected to the driving transistor through a hole penetrating a passivation layer in the pixel circuit layer PCL. The first electrode ELT1 may be etched to expose at least a portion of the pixel circuit layer PCL.

The patterning of a pixel defining film (S200) includes depositing the pixel defining layer PDL on the pixel circuit layer PCL. The pixel defining film PDL may be etched to expose at least a portion of the first electrode ELT1. The pixel defining film PDL may be etched so as to overlap the remaining portion of the first electrode ELT1 in a plan view.

The patterning of a partition wall SW on a pixel circuit layer PCL (S300) will be described with reference to FIG. 8, FIG. 10, and FIG. 13 to FIG. 15.

The partition wall SW may be deposited to have a multi-layered structure. For example, the first layer L1, the second layer L2, and the third layer L3 may be sequentially deposited on the pixel circuit layer PCL based on the third direction DR3. The first layer L1 and the third layer L3 may include one or more of the transition metals such as titanium (Ti), niobium (Nb), tantalum (Ta), and the like, as described above. The second layer L2 may include molybdenum (Mo) having small contact resistance.

The first layer L1 may be deposited to have the first thickness d1. The second layer L2 may be deposited to have the second thickness d2. The third layer L3 may be deposited to have the third thickness d3. The partition wall SW may be deposited to have the fourth thickness d4 that is the sum of the first thickness d1 to the third thickness d3.

When depositing the partition wall SW, the first layer L1 of the first layer L1 to the third layer L3 may be deposited to be the thickest. The first layer L1 may be deposited such that the first thickness d1 occupies half or more of the fourth thickness d4. As the first layer L1 is formed such that the first thickness d1 occupies half or more of the fourth thickness d4, the first thickness d1 of the first layer L1 may correspond to the light emitting thickness E1 of the light emitting portion EL to be deposited later. The light emitting thickness E1 of the light emitting portion EL may be about 0.2 μm to about 0.3 μm.

A dry etching process may be performed on the first layer L1 to the third layer L3 in consideration of the material of each layer. The first layer L1, the second layer L2, and the third layer L3 may be patterned through two or more etching processes. A photoresist PR for etching may be disposed on the third layer L3. An etching gas may be utilized in the process of etching the partition wall SW.

Considering the material of each layer, the third layer L3 may be etched by a Cl-based etching gas. The second layer L2 may be etched by an F-based etching gas. The first layer L1 may be etched by a Cl-based etching gas. The first layer L1 to the third layer L3 may be etched to have end portions corresponding to each other. As used herein, “having end portions corresponding to each other” may mean “having end portions coincident with each other overlapping in a plan view”.

After the first layer L1 to the third layer L3 are etched to have end portions coincident with each other, the photoresist PR may be removed. After the photoresist PR is removed, the second layer L2 may be etched relatively deeper than the first layer L1 and the third layer L3. The first layer L1 and the third layer L3 may further protrude to the edge than the second layer L2. The second layer L2 may be etched so that the first layer L1 and the third layer L3 each form a tip. The tip may form the protrusion PRU. The first layer L1 may be formed to have the first protrusion PRU1. The third layer L3 may be formed to have the second protrusion PRU2. The second protrusion PRU2 may be formed to have the protruding length P1.

The partition wall SW may form an under-cut structure. At least a portion of the first layer L1 and the third layer L3 may not overlap the second layer L2 in a plan view. The first layer L1 and the third layer L3 may have end portions that do not correspond to the second layer L2. The end portions of the first layer L1 and the third layer L3 may not coincide with the end portion of the second layer L2. The end portions of the first layer L1 and the third layer L3 may have the protrusions PRU corresponding to each other.

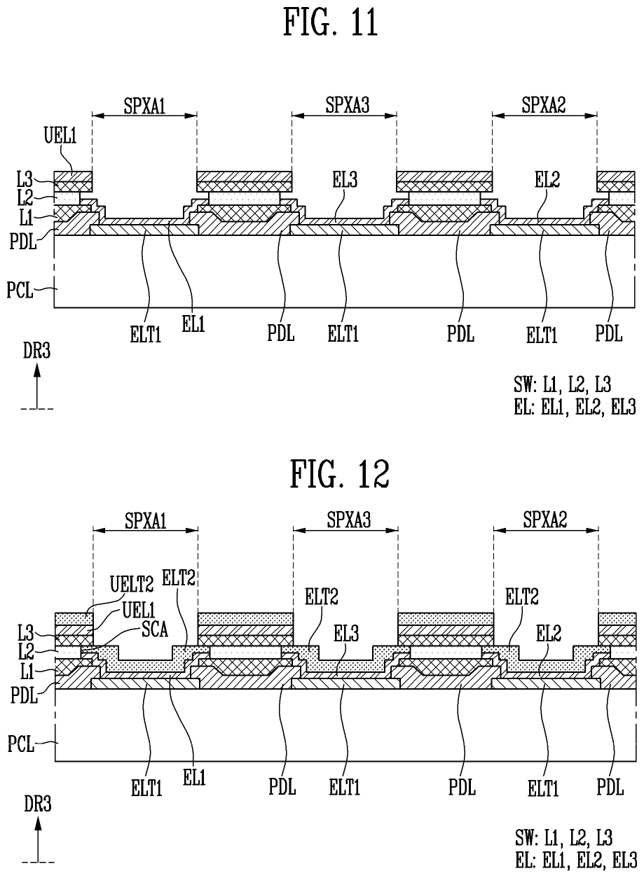

The patterning of the light emitting portion EL (S400) will be described with reference to FIG. 8, FIG. 11, and FIG. 16. The patterning of the light emitting portion EL includes patterning the first light emitting portion EL1 defining the first sub-pixel area SPXA1 and the second light emitting portion EL2 defining the second sub-pixel area SPXA2.

The light emitting portion EL may be deposited on the first electrode ELT1 after the second layer L2 is etched. When depositing the light emitting portion EL, an evaporator may be utilized. According to some embodiments, the evaporator is a vacuum evaporator. The light emitting portion EL may be deposited to have the thickness E1 of the light emitting portion corresponding to that of the first layer L1. The light emitting portion EL may contact the side surface of the first layer L1.

At least a portion of the light emitting portion EL may be deposited on the side surface of the second layer L2. The light emitting portion EL may be deposited along a second deposition direction 2 due to a shadow effect by the first layer L1. The light emitting portion EL may be deposited along a first deposition direction 1 due to a shadow effect by the third layer L3. As used herein, the shadow effect may refer to an effect in which the deposition material is not formed in at least a partial area due to obstacles overlapping the deposition direction when the deposition material is deposited.

The light emitting portion EL may be deposited on the second layer L2 in an area in which the directions of the first deposition direction 1 and the second deposition direction 2 extend by the shadow effect. The area in which the directions of the first deposition direction 1 and the second deposition direction 2 extend may refer to an area in which the light emitting portion EL may be deposited on the side surface of the second layer L2. An area excluding the area in which the directions of the first deposition direction 1 and the second deposition direction 2 extend may mean the side contact area SCA. To electrically connect the second electrode ELT2 and the second power line PL2, it is desirable to provide the side contact area SCA in which the second electrode ELT2 may be electrically connected to the second layer L2.

The light emitting portion EL may be formed by an evaporator, and in this case, the deposition angle of the light emitting portion EL may be difficult to control. The deposition angle of the light emitting portion EL may be predetermined. Accordingly, in order for the light emitting portion EL to be selectively deposited to form the side contact area SCA, it is desirable to adjust the deposition area.

Experimentally, when the first layer L1 does not protrude more than the second layer L2 (e.g., when the partition wall SW has a ‘T’-shaped structure), because only the third layer L3 provides a shadow effect, the protruding length P1 of the protrusion PRU needs to be increased. In this case, to properly form the side contact area SCA, the second layer L2 needs to be more deeply etched (e.g., the protruding length P1 is about 0.35 μm to about 0.7 μm). When the second layer L2 is more deeply etched and the width of the partition wall SW is reduced, structural stability may be damaged, so there is a need to increase the second width W2. Accordingly, as the width of the partition wall SW is considerably increased, a structure in which the second layer L2 is further deeply etched is required. In the end, according to the conventional structure, the width of the partition wall SW between the sub-pixels SPX increases due to the process issue, and it may be difficult to provide a high-resolution display device DD.

However, when the second layer L2 is etched so that the first layer L1 forms the first protrusion PRU1 and when the light emitting portion EL is deposited so that the light emitting thickness E1 corresponds to the first thickness d1, the aforementioned process risk may be reduced. That is, according to the structure according to some embodiments, the need for excessive extension of the second protrusion PRU2 of the third layer L3 is reduced, the first layer L1 may closely support the structure of the partition wall SW, and the side contact area SCA may be clearly secured (e.g., reliably produced). As a result, because the width of the partition wall SW may be reduced, the resolution of the display device DD may be improved (e.g., increased).

As the need for excessive extension of the second protrusion PRU2 of the third layer L3 is reduced or substantially reduced, the etching depth of the second layer L2 may be reduced. That is, according to the structure according to some embodiments, the second layer L2 may be etched to a minimum depth. As the second layer L2 is etched to the minimum depth, the protruding length P1 may be about 0.1 μm to about 0.2 μm.

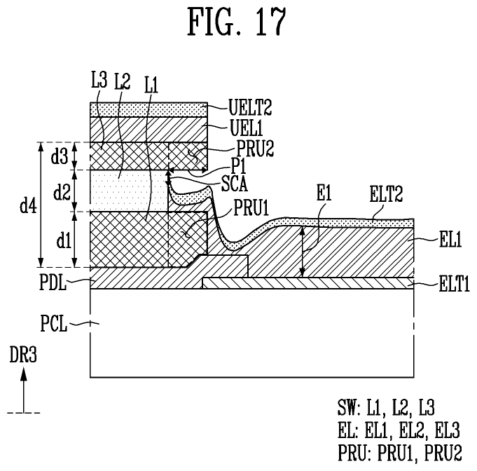

The patterning of the second electrode ELT2 (S500) will be described with reference to FIG. 8, FIG. 12, and FIG. 17.

After depositing the light emitting portion EL, the second electrode ELT2 may be deposited on the light emitting portion EL. The second electrode ELT2 may be electrically connected to the light emitting portion EL.

The second electrode ELT2 may be deposited by using a rotary sputter. The deposition angle of the second electrode ELT2 may be controllable. Because the second electrode ELT2 includes a conductive material that is an inorganic material, the deposition incident angle may be greater than that of the light emitting portion EL including an organic material.

The second electrode ELT2 may electrically contact the side surface of the second layer L2. As described above, because the side contact area SCA may be closely secured (e.g., reliably produced), the second electrode ELT2 may stably electrically contact the side surface of the second layer L2.

The upper second electrode UELT2 and the upper light emitting portion UEL1 may then be etched through the same etching process to expose at least a portion of the third layer L3.

It will be understood that, although the terms “first”, “second”, “third”, etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section discussed below could be termed a second element, component, region, layer or section, without departing from the spirit and scope of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. In addition, it will also be understood that when a layer is referred to as being “between” two layers, it can be the only layer between the two layers, or one or more intervening layers may also be present.

The terminology used herein is for the purpose of describing particular embodiments and is not intended to be limiting of the inventive concept. As used herein, the singular forms “a” and “an” are intended to include the plural forms as well, unless the context clearly indicates otherwise. It will be further understood that the terms “include,” “including,” “comprises,” “comprising,” “has,” “have,” and “having,” when used in this specification, specify the presence of stated features, integers, steps, operations, elements, and/or components, but do not preclude the presence or addition of one or more other features, integers, steps, operations, elements, components, and/or groups thereof.

As used herein, the term “and/or” includes any and all combinations of one or more of the associated listed items. For example, the expression “A and/or B” denotes A, B, or A and B. Expressions such as “one or more of” and “at least one of,” when preceding a list of elements, modify the entire list of elements and do not modify the individual elements of the list. For example, the expression “one or more of A, B, and C,” “at least one of A, B, or C,” “at least one of A, B, and C,” and “at least one selected from the group consisting of A, B, and C” indicates only A, only B, only C, both A and B, both A and C, both B and C, or all of A, B, and C.

Further, the use of “may” when describing embodiments of the inventive concept refers to “one or more embodiments of the inventive concept.” Also, the term “exemplary” is intended to refer to an example or illustration.

It will be understood that when an element or layer is referred to as being “on”, “connected to”, “coupled to”, or “adjacent” another element or layer, it can be directly on, connected to, coupled to, or adjacent the other element or layer, or one or more intervening elements or layers may be present. When an element or layer is referred to as being “directly on,” “directly connected to”, “directly coupled to”, “in contact with”, “in direct contact with”, or “immediately adjacent” another element or layer, there are no intervening elements or layers present.

As used herein, the term “substantially,” “about,” and similar terms are used as terms of approximation and not as terms of degree, and are intended to account for the inherent variations in measured or calculated values that would be recognized by those of ordinary skill in the art.

As used herein, the terms “use,” “using,” and “used” may be considered synonymous with the terms “utilize,” “utilizing,” and “utilized,” respectively.

When one or more embodiments may be implemented differently, a specific process order may be performed differently from the described order. For example, (i) the disclosed operations of a process are merely examples, and may involve various additional operations not explicitly covered, and (ii) the temporal order of the operations may be varied.

Unless otherwise defined, all terms (including technical and scientific terms) used herein have the same meaning as commonly understood by one of ordinary skill in the art to which the present inventive concept belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification.

While aspects of some embodiments of the present disclosure have been shown and described with reference to certain embodiments thereof, it will be understood by those skilled in the art that various changes in forms and details may be made therein without departing from the spirit and scope of embodiments according to the present disclosure as defined by the appended claims and their equivalents.

Therefore, the technical scope of the disclosure may be determined by on the technical scope of the accompanying claims, and their equivalents.

What is claimed is:

1. A display device comprising:
a pixel circuit layer comprising a base layer and a pixel circuit;
a first electrode on the pixel circuit layer;
light emitting portions on the first electrode and comprising a first light emitting portion defining a first sub-pixel area and a second light emitting portion defining a second sub-pixel area; and
a partition wall between the first light emitting portion and the second light emitting portion,
wherein the partition wall comprises a first layer, a second layer on the first layer, and a third layer on the second layer,
wherein the first layer has a first thickness, the second layer has a second thickness, the third layer has a third thickness, and the partition wall has a fourth thickness that is a sum of the first thickness to the third thickness, and
wherein the first thickness and a thickness of the light emitting portion correspond to each other.

2. The display device of claim 1, wherein a difference between the first thickness and the thickness of the light emitting portion is 0.1 μm or less.

3. The display device of claim 2, wherein the first thickness is more than half of the fourth thickness.

4. The display device of claim 2, wherein the first thickness is 0.2 μm to 0.3 μm.

5. The display device of claim 1, wherein the first layer has a first width, the second layer has a second width, and the third layer has a third width, and
wherein the first width is greater than the second width.

6. The display device of claim 1, wherein at least a portion of the first layer does not overlap the second layer in a plan view.

7. The display device of claim 5, wherein the third width corresponds to the first width.

8. The display device of claim 5, wherein the second width is 0.15 μm to 0.25 μm.

9. The display device of claim 7, wherein a difference between the third width and the first width is 0.05 μm or less.

10. The display device of claim 1, wherein the first layer and the third layer comprise a same metal, and
wherein the second layer comprises a different metal than the first layer and the third layer.

11. The display device of claim 10, wherein the first layer and the third layer comprise titanium (Ti), and
wherein the second layer comprises molybdenum (Mo).

12. The display device of claim 1, further comprising
a second electrode on the light emitting portions,
wherein the first electrode is an anode electrode,
wherein the second electrode is a cathode electrode, and
wherein the second electrode is in contact with at least a portion of the second layer.

13. A manufacturing method of a display device, the method comprising:
forming a pixel circuit layer comprising a pixel circuit on a base layer;
patterning a first electrode on the pixel circuit layer;
patterning a partition wall on the pixel circuit layer;
patterning a light emitting portion; and
patterning a second electrode electrically connected to the light emitting portion,
wherein the patterning of the light emitting portion comprises patterning a first light emitting portion defining a first sub-pixel area and a second light emitting portion defining a second sub-pixel area,
wherein the patterning of the partition wall comprises depositing a first layer, a second layer on the first layer, and a third layer on the second layer,
wherein the first layer has a first thickness, the second layer has a second thickness, and the third layer has a third thickness,
wherein the partition wall has a fourth thickness that is a sum of the first thickness to the third thickness, and
wherein the first thickness and the a thickness of the light emitting portion correspond to each other.

14. The manufacturing method of the display device of claim 13, wherein a difference between the first thickness and the thickness of the light emitting portion is 0.05 μm or less.

15. The manufacturing method of the display device of claim 13, wherein the first thickness is greater than the second thickness and the third thickness.

16. The manufacturing method of the display device of claim 13, wherein the thickness of the light emitting portion is 0.2 μm to 0.3 μm.

17. The manufacturing method of the display device of claim 13, wherein the patterning of the partition wall comprises etching the second layer deeper than the first layer and the third layer.

18. The manufacturing method of the display device of claim 17, wherein the third layer forms a protrusion having a protruding length.

19. The manufacturing method of the display device of claim 18, wherein the protruding length is 0.1 μm to 0.2 μm.

20. The manufacturing method of the display device of claim 13, further comprising:
patterning the second electrode on the light emitting portion,
wherein the patterning of the light emitting portion comprises depositing the light emitting portion by using an evaporator, and
wherein the patterning of the second electrode comprises depositing the second electrode by using a rotary sputter.
